(19) United States
(12) Patent Application Publication
(10) Pub. No.: US 2005/0187754 A1
(43) Pub. Date: Aug. 25, 2005

(54) Software-based keystroke eliminator for alpha-numeric keyboards and keypads

(76) Inventor: Dana Suess, Homer Glen, IL (US)

Correspondence Address: QUARLES & BRADY STREICH LANG, LLP, ONE SOUTH CHURCH AVENUE, SUITE 1700, TUCSON, AZ, 85701-1621, US

(21) Appl. No.: 11/009,363

(22) Filed: Dec. 9, 2004

Related U.S. Application Data
(60) Provisional application No. 60/528,289, filed on Dec. 9, 2003.

(51) Int. Cl. G06F 17/28; H03M 11/00

(52) U.S. Cl. 704/4

(57) ABSTRACT

A keyboard or keypad driver and method that, by monitoring and analyzing user keystrokes (input), introduces it's own keystrokes to the data stream, thereby reducing the need for the user to hit the Shift, Period, Question mark, Apostrophe and Num keys.

### CROSS-REFERENCE TO RELATED APPLICATION

This application claims the filing date of U.S. Provisional Application Ser. No. 60/528,289 filed on Dec. 9, 2003 by the same inventor.

### REFERENCE TO COMPUTER PROGRAM LISTING APPENDIX

A computer program listing appendix containing the source code of a computer program that may be used with the present invention is incorporated herein by reference and appended hereto as one (1) original compact disk, and an identical copy thereof, containing a total of 2 files as follows: Dusty Keys source code from provisional 12-9-03.txt (139 kb; created Dec. 9, 2003); Dusty Keys source code from current version 12-7-04.txt (368 kb; created Dec. 7, 2004).

### BACKGROUND

1. Field of the Invention

The invention relates in general to the field of data entry interfaces, such as keyboards and the like, and more particularly to keyboards and keypads and software methods useful for the rapid entry of data into hand-held electronic devices (such as a cellular phone or personal digital assistant).

Definitions

Keyboard vs. Keypad—essentially the same, with keypads typically being smaller than keyboards.

Keypad Driver—software that senses and acts on keystrokes typed on computer keyboards and keypads.

Legal Word—a word found in the dictionary, examples: “Hello” “Cat” “Dog”, etc. On the other hand, “ttteteu” is not a legal word.

Overloading—to save room (and sometimes cost), manufactures often put two or more characters on the same key, thereby “overloading” the key. This is generally done when space constraints exist and a minimal button count is desired. This necessitates putting two or more letter/number/punctuation characters on each button, as can be seen in FIGS. 2-9. Overloaded keypads generally need “modal” keys such as “Shift”, “Ctrl”, “Alt”, and “Num” keys, that are pressed when user wishes to enter alternative data. Example—the shift key, when pressed and held, causes letters typed to be interpreted and displayed as capital letters. Another example of a modal key is the “Num” key, which when pressed and released, causes subsequent keystrokes on overloaded keys to be interpreted as digits, not characters. The “Num” key is then pressed a second time to exit “Numeric mode,” causing keystrokes on overloaded keys to be interpreted as characters again. For example, in the keyboard in FIG. 5, when in character mode, each key hit generates a letter. So in numeric mode, the same keystrokes needed to spell “teeth” will generate the digits “21120”.

Cursor—a visual and mathematical locator of where letters, digits and punctuation will be inserted or appended at when a user types.

Modal keys: Generally two types of modal function keys exist:
1) Keys that are pushed and held while other keys are typed, such as a Shift key.
2) Keys that are pushed and released which enters a mode, allowing subsequent data keys, such as digits, to be hit. The Num key is hit a second time to “exit” Num mode, allowing letters to be entered again.

Defcon is a status variable.

Candidate key is any key that has both a letter A-Z and a digit printed on it.

2. Description of the Related Art

The first typewriter worked with three or four rows of fingertip size buttons called “keys.” The outstretched fingers of the hands of the typist could depress each key as the entire layout of keys was designed to be approximately the width of two hands. From this simple beginning, the typewriter has given rise to a plethora of data entry interfaces based on the underlying concept of the tactile input of text-based information. Indeed, everyone who has used a typewriter or computer in the last ten years is familiar with data entry interfaces known simply as “keyboards,” “keypads,” or even “touch screens.” The terms keyboard and keypad can be used interchangeably, with “keyboards” generally referring to relatively large devices designed for desktop use and “keypads” generally referring to smaller, handheld devices such as cell phones and PDA's.

Keyboards and keypads are still the preferred means for entering information into devices such as hand-held electronic devices, computers, and cell phones. Normally, keyboards include the ability to enter numbers, alphabetic characters, punctuation, and control characters. At least for the English language (and others utilizing the 26 characters of the Roman alphabet), the ubiquitous “QWERTY” keyboard arrangement has become the de-facto standard layout of letter characters, numbers, and punctuation. An illustration of the standard QWERTY keyboard layout is shown in FIG. 1. Other keypad layouts, exhibiting various key arrangements and degrees of overloading, can be seen in FIGS. 2-9. All previous keypad drivers simply did rote processes of reading and reporting keystrokes.

A problem with all of the above keyboards is that, in addition to the letters, numbers, and punctuation buttons hit in the course of normal typing, the user must also hit the following five buttons:
1) Shift Key to capitalize the beginning of sentences such as “Hello there.” and words like “Dr.” and “FBI”.
2) Period Key to end sentences such as “Hello there.” and words like “Dr.” and “FBI”.
3) Question Mark Key to end sentences such as “How are you?”
4) Apostrophe Key to enter words such as “Don't” and “Haven't”.
5) Num Key for keyboards that overload digits onto character buttons such as those in FIGS. 2-9.

A NUM key is a modal key used to enter digits. Normally, the Num key is pressed once to put the keypad into “Numeric” mode in which further input will be assumed to be digits. These digit(s) are then entered, then the Num key is pressed again to take the keypad “out of Num mode” and further input will be assumed to be characters A-Z, etc.

In view of the above, it would be desirable to have a data entry interface that could add periods, question marks, apostrophes, capitalization and determine if the user intended to enter a number or a word by seeing if the entry spells a word or not. If it does not spell a word, the user must have entered a number and the invention converts the letters to numbers. This would allow faster data entry.

### SUMMARY OF THE INVENTION

The invention relates in general to a software-based, keystroke eliminator incorporated into a keyboard/keypad driver. More specifically, the invention provides in one embodiment a keypad driver that monitors the user's keystrokes, looking for opportunities to capitalize letters, insert punctuation such as periods, question marks and apostrophes, convert certain sequences of characters (“aliases”) to others, and detect and convert keystroke sequences that could only be numbers (because they are not in a dictionary of words) from letters to numbers. Accordingly, the keystroke eliminator invention expedites the typing of text and other information on keypads and keyboards.

The invention works on any type of keyboard/keypad. QWERTY, Delta II, Alphabetic, and other keypad layouts that use, amongst others, the letters A-Z plus the numbers 0-9. See FIGS. 1-9.

Preferably, the invention utilizes existing keyboard structures or keypad button configurations as are found on cellular telephones, personal digital assistants, and the like. However, other data entry structures, such as 5×6 button keypads, a “touch pad,” or electronic display screen, are also contemplated by the inventor.

Thus, it is a primary objective of the invention to provide a data entry interface that expedites data entry by eliminating keystrokes that the keypad driver software can perform for the user by examining the user data stream of keystrokes, looking at every letter, word and sentence.

Further, an object of the invention is to provide a modified QWERTY layout that facilitates the rapid entry of data on hand-held electronic devices.

Another object of the invention is to provide a keyboard or keypad layout that is adaptable for use with a wide variety of electronic devices.

Yet another object of the invention is to provide a data input interface that is familiar to users of the standard QWERTY character layout yet compact enough to fit on a variety of small electronic devices.

Still another object of the invention is to provide improved keypads or keyboards for small electronic devices that enhance the efficiency of data entry, thereby promoting the use of text entry and acquisition of data on these devices.

Yet another object of the invention is to provide a keyboard driver that allows using a thumb of each hand more efficiently than keyboards or keypads found on existing hand-held devices.

An additional object of the invention is to provide a keypad or keyboard that is easy to use on a hand-held electronic device yet economical to produce.

Another object of the invention is to provide a keypad or keyboard on a small electronic device that provides a means for eliminating or reducing the need to use certain keystrokes.

Another object of the invention is to be applicable to all keyboard and keypad arrangements, such as those seen in FIGS. 1-9.

In accordance with these and other objects, there is provided a new and improved method of processing, and thereby reducing, user keystrokes on data entry interfaces.

Various other purposes and advantages of the invention will become clear from its description in the specification that follows. Therefore, to the accomplishment of the objectives described above, this invention includes the features hereinafter fully described in the detailed description of the preferred embodiments, and particularly pointed out in the claims. However, such description discloses only some of the various ways in which the invention may be practiced.

### BRIEF DESCRIPTION OF THE DRAWINGS

FIG. 1 Standard QWERTY keyboard with separate buttons for letters and numbers.

FIG. 2 QWERTY keyboard with 3×4 numeric matrix superimposed.

FIG. 3 QWERTY keyboard with digits overloading the top row of letter keys.

FIG. 4 Alphabetic keypad overloaded with a 3×4 button digit matrix.

FIG. 5 Delta II keypad overloaded with a 3×4 button digit matrix aligned towards the top of button matrix.

FIG. 6 Delta II keypad overloaded with a 3×4 button digit matrix aligned towards the bottom of button matrix.

FIG. 7 Standard 12 button phone keypad with keys overloaded to accommodate letters and digits.

FIG. 8 Delta II/Dusty Keys enabled device. Preferred embodiment of invention.

FIG. 9 Delta II/Dusty Keys enabled device displaying a punctuation character screen.

FIG. 10 is a flow chart showing a digital processing device.

FIG. 11 depicts process steps of an embodiment of the invention.

FIG. 12 depicts process steps of another embodiment of the invention.

FIG. 13 depicts process steps of a third embodiment of the invention.

FIG. 14 depicts process steps of a fourth embodiment of the invention.

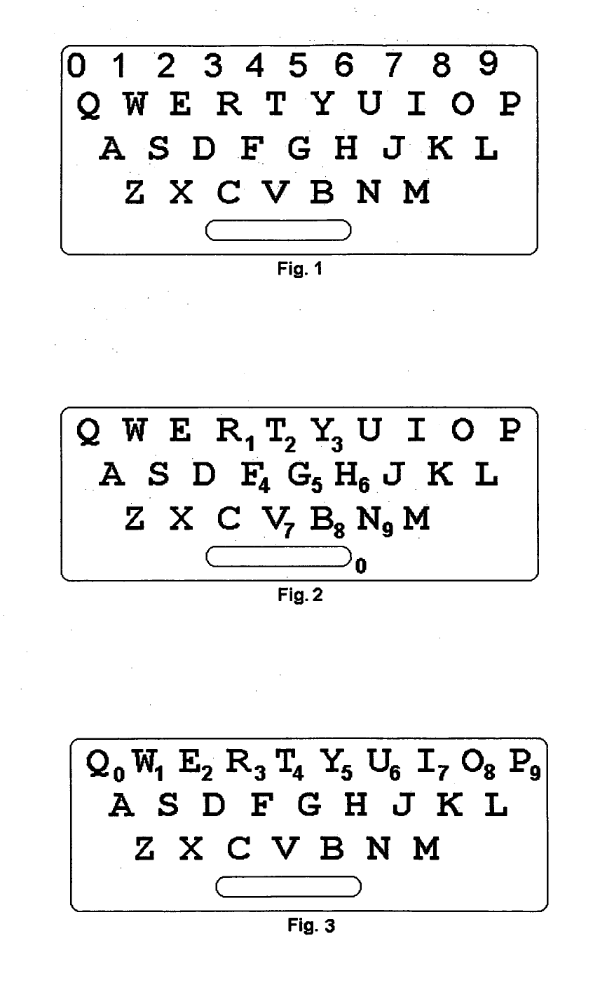

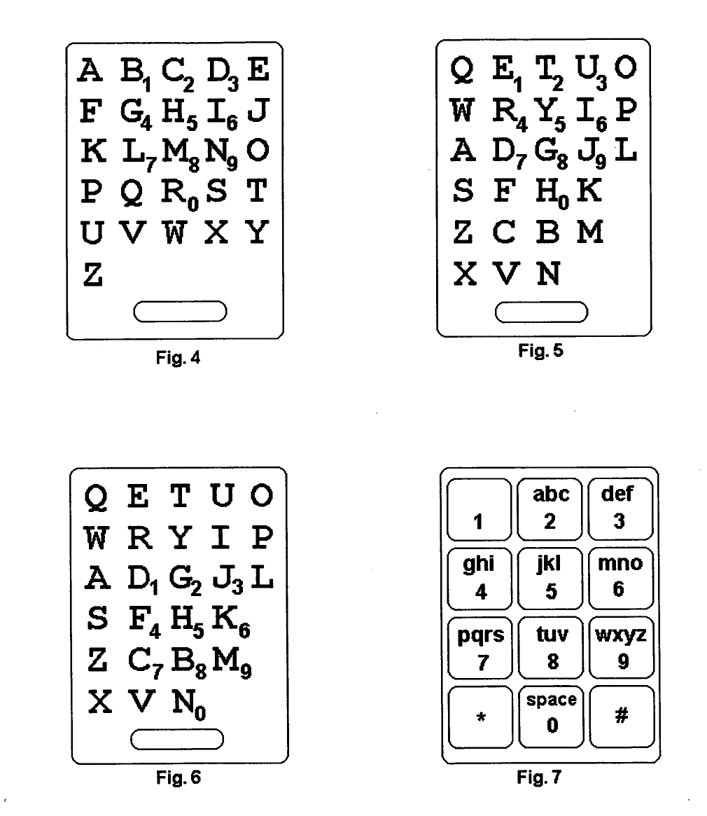

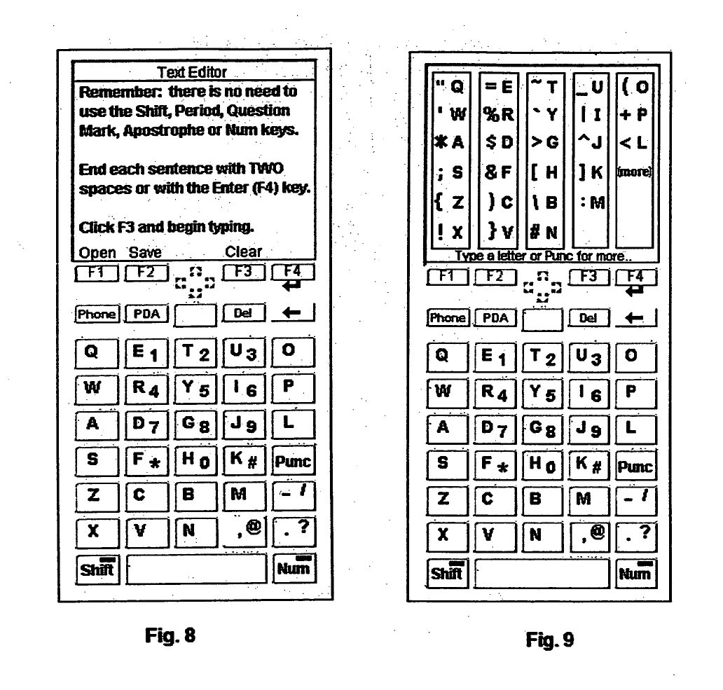

### DETAILED DESCRIPTION OF THE PREFERRED EMBODIMENTS

The invention disclosed herein may be implemented as a method, apparatus or article of manufacture using standard programming or engineering techniques to produce software, firmware, hardware, or any combination thereof. The term “article of manufacture” as used herein refers to code or logic implemented in hardware or computer readable media such as optical storage devices, and volatile or non-volatile memory devices. Such hardware may include, but is not limited to, field programmable gate arrays (“FPGAs”), application-specific integrated circuits (“ASICs”), complex programmable logic devices (“CPLDs”), programmable logic arrays (“PLAs”), microprocessors, or other similar processing devices.

An important purpose of the invention is to allow people to type faster and more comfortably on their cell phones and other small devices having space and dimensional constraints by reducing necessary keystrokes. Thus, the main components of the invention include a keypad and a keypad driver that intelligently processes the users keystrokes in such a way that allows the keypad driver to “second guess” the user. The user simply keeps on typing, without hitting the Shift, Period, Question mark, Apostrophe or Num keys. The user signals the end of a sentence by typing either TWO spaces, the Enter (Return) key, or the Down Arrow (soft arrow) key. This allows the driver to detect the end of a sentence and modify the data accordingly and the user to enter fewer keystrokes than they would have without the invention.

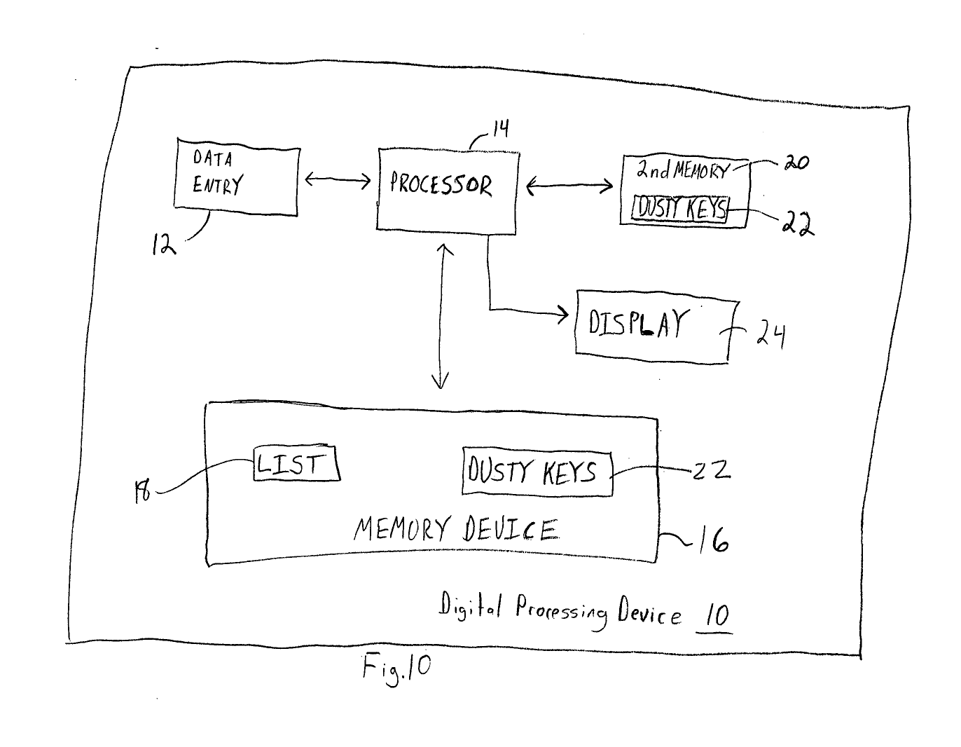

Referring to the figures, wherein like parts are designated with the same reference numerals and symbols, FIG. 10 illustrates a digital processing device 10 according to the invention. The digital processing device 10 includes a data entry device 12, a processor 14, and a memory device 16. In this embodiment of the invention, the digital processing device 10 may be a wireless telephone, a personal digital assistant (“PDA”), a portable computer, or other communication device. The data entry device 12 may be a keyboard or a keypad. The processor 14 may be a micro-processor, an embedded processor, a field-programmable gate array (“FPGA”), an application-specific integrated circuit (“ASIC”), complex programmable logic device (“CPLD”), a programmable array logic (“PAL”), a programmable logic array (“PLA”), or other programmable logic device. The memory device 16 may be a random access memory (“RAM”), a read-only memory (“ROM”), a flash memory device, a cache memory device, or other type of memory.

The memory device 16 contains a database of legal words (“list”) 18. Additionally, the memory device 16 or a second memory device 20 includes a software application (“dusty keys”) 22. In order to implement the dusty keys application, computer instructions residing within the software application are loaded into the processor 14. Data is entered into the digital processing device 10 by way of the data entry device 12. Once invoked, the dusty keys application compares input data to the list 18 to determine if a currently entered word or partial work is considered to be a legal word. A display surface 24 provides an output interface allowing a user to see the results of entering data into the data entry device and the application of the dusty keys software application. If the data entry device is a touch-screen, the data entry device may also be used as the display surface.

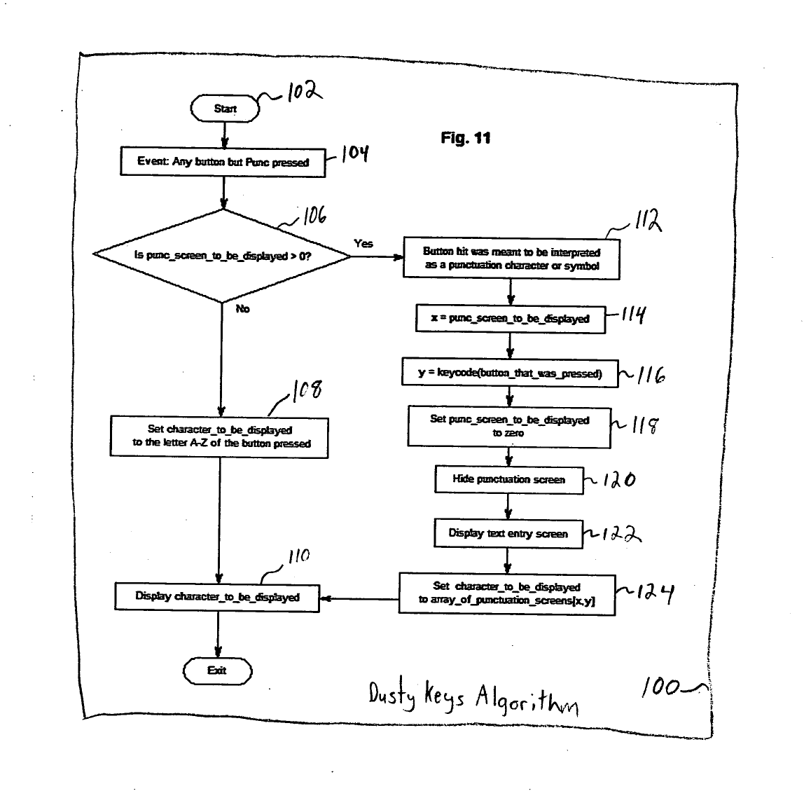

A dusty keys algorithm 100 is illustrated by the flow chart of FIG. 11. In step 102, the dusty keys application 22 is invoked by the processor 14. In step 104, a button on the data entry device 12 is depressed by a user. In this embodiment of the algorithm 100, the depressed button is any key other than a Punctuation Modal key. In step 106, a variable, punc_screen_to_be_displayed, is examined to determine if the display surface 24 should indicate punctuation symbols rather the letters or numbers.

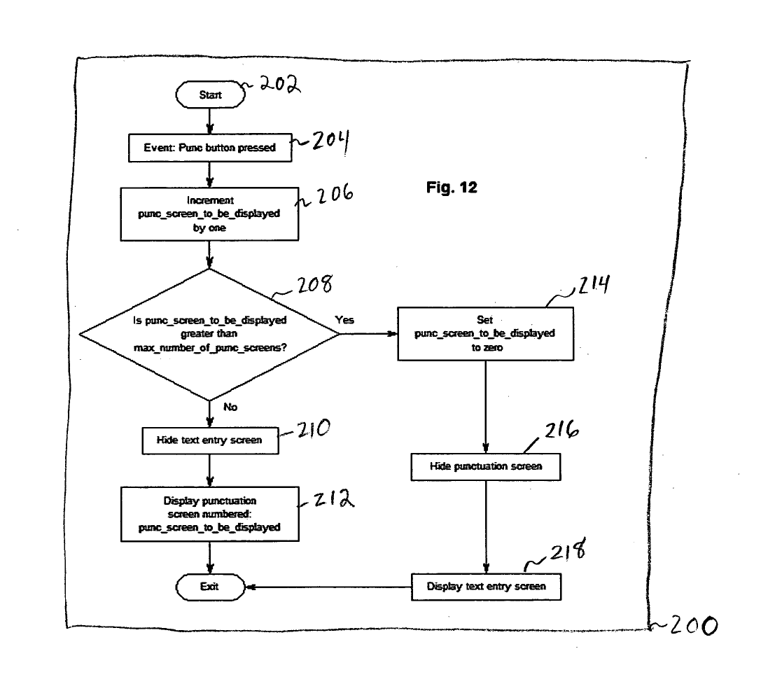

The variable is: punc_screen_to_be_displayed shown in FIGS. 11 and 12. It starts at zero and is incremented by one (to the maximum number of button-to-punctuation mapping screens (one of which is shown in FIG. 9) each time the punctuation button is pressed. If punc_screen_to_be_displayed reaches its maximum value, (the maximum number of screens the user has selected) it is set to zero, then punctuation screen is hidden and the text entry screen is displayed for further text entry.

If the punctuation variable is not set, the dusty keys algorithm 100 proceeds to step 108 wherein the character display variable is set to a letter. In step 110, the contents of the character display variable are sent to the display surface.

If the punctuation variable is set, the dusty keys algorithm 100 proceeds to step 112. In step 114, a placeholder variable x is set to indicate that the punctuation screen is to be displayed. In step 116, a second placeholder variable y is set to a value representative of the button that was pressed. In step 118, the punctuation variable is reset and the punctuation screen is removed from the display surface in step 120. Subsequently, the display surface 24 displays a text entry screen in step 122. In step 124, the variable indicating what character is to be displayed is set to a character residing within a character array at a location referenced by the x and y variables. The algorithm 100 proceeds to step 110 wherein the character to be displayed is sent to the display surface.

Another dusty keys algorithm 200 is displayed in FIG. 12. In step 202, the dusty keys application 22 is invoked by processor 14. In step 204, a button on the data entry device 12 is depressed by a user. In this algorithm 200, the depressed button is a Punctuation Modal button. In step 206, the punctuation screen variable is increased by one. In step 208, the punctuation screen variable is compared to a maximum number of punctuation screens variable. If the punctuation screen variable is greater than the maximum number of punctuation screens variable, the algorithm proceeds to step 214 wherein the punctuation screen variable is reset. In step 216, the punctuation screen is no longer displayed on the display surface 24. In step 218, the display surface displays a text screen.

If the punctuation screen variable is less than the maximum number of punctuation screens variable in step 208, the text entry screen is no longer displayed, as indicated in step 210. In step 212, a punctuation screen corresponding to the punctuation screen variable is displayed on the display surface.

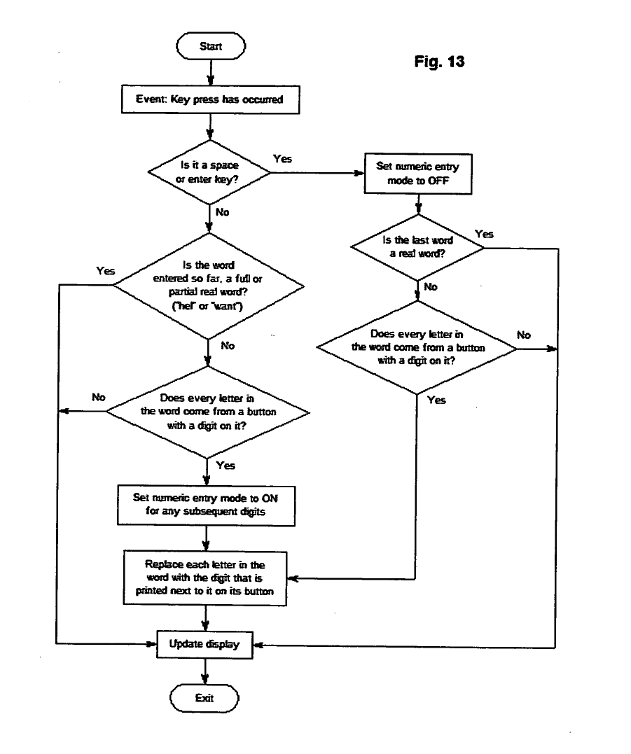

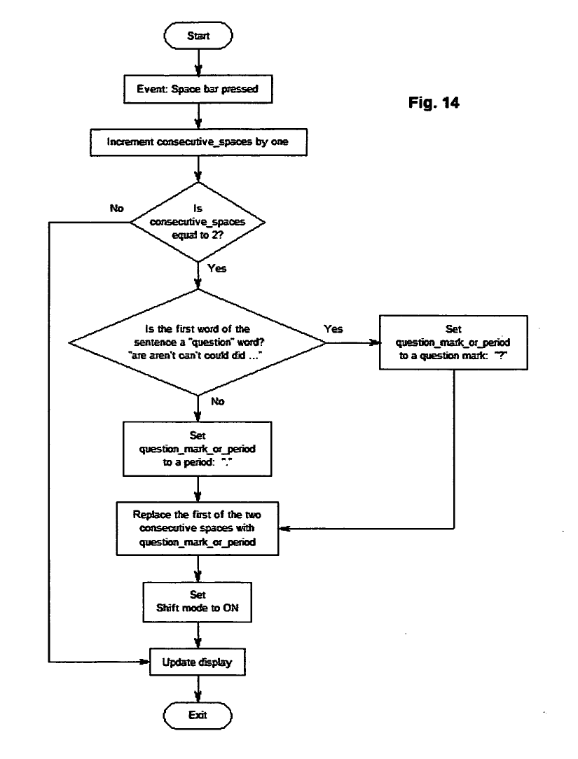

Further illustrations of the invention are depicted in FIGS. 13 and 14. A dusty keys application uses “keystroke eliminator” technology to reduce or eliminate the need to use the following keys while typing:
1) Period
2) Question Mark
3) Apostrophe
4) Shift Key
5) Num Key

A user simply types the same way he or she is used to, except the user does not bother clicking any of the above mentioned five keys.

Click two spaces, or use the F4/Enter Key, or the Down Arrow to complete each sentence. A dusty keys application does the rest including:
AutoShift—capitalizes sentences;
AutoSentence—adds a period or question mark to the sentence you just typed, and prepares for the beginning of your next sentence. For example:
You type: hello welcome to instant speed
You get: Hello. Welcome to instant speed.
You type: hi did my order ship thanks
You get: Hi. Did my order ship? Thanks.

If you do not want punctuation at the end of your sentence, use the Down Arrow key instead of the Enter key to finish the sentence:
RACE IT LIKE YOU STOLE IT

AutoAlias—user programmable:
sf becomes San Francisco
dk becomes Dusty Keys tm
bb becomes Bed & Breakfast etc.

AutoNum—no need to click the Num button to enter numbers. During or immediately after you type a number, AutoNum “disambiguates” an entry, instantly changing from text to numeric mode, and updating the display.
You type: see you in y minutes
(“y” is also the “5” button.)
You get: See you in 5 minutes.

AutoNum works with numbers such as:
123 −0.002 $50.00 33%
6-14-2005 1,000,000 24/7
#25 35 mm (888) 123-4567
7:15 pm 60/40 .45 2,999.95
1-800 GOPIZZA 1,000!!!! etc.

If a user wants to type a single capital letter as in: “I am at gate E now,” he or she uses the Shift key to enter the capital letter. AutoNum leaves uppercase letters alone. Lower and upper case examples:
You type: route ii You get: Route 66
You type: delta II You get: Delta II

If one wants to type something like “Z8,” click the Num key after “Z.” Clicking the Num key once (or twice) turns Auto-Num off for the current word a user is typing, allowing him or her to enter mixed data like: Part #: A3-E177-006.

A handful of numbers (out of trillions) happen to spell out a word on the Delta II keypad (FIG. 6). For example, the numbers “6” and “245” use the same keys as the words “I” and “try.” If a user ever needs to type one of these numbers, click the Num key before typing the number. No need to press the Num key a second time to turn Num mode off, the dusty keys application does it when you click the space bar or Enter key. If one types “We ran 6.0 miles” or “It feels like −245 degrees outside” or “1, 2, 3, 4, 5, 6, 7, 8, 9,” one does not need to use the Num key.

Only in rare circumstances will one need to use the Num key, and one will never need it when typing longer numbers such as phone numbers and credit card numbers.

AutoCap—capitalizes letters as needed:
tba becomes TBA
ste. becomes Ste.
ca becomes CA
mrs smith becomes Mrs. Smith
dear mr long becomes Dear Mr. Long
fri becomes Fri, etc.

AutoApostrophe:
You type: dont cant havent . . .
You get: don't can't haven't . . .

Punc Key—used to enter additional punctuation characters not seen on the keypad. After clicking the Punc key, click the button on the keypad corresponding to the punctuation character a user wants to enter. For example, after clicking the Punc key, click the D key to enter a dollar sign ($) or the A button for an asterisk (*), or an E for an equal sign (=), etc. A user can continue to click or hold the key he or she picked—for example: Hello!!!! Or a user can click the Punc key a second time to display more punctuation characters to select from. Clicking the Punc key a third time exits the Punc screens without entering anything.

Shift Key—click to capitalize the next letter you type. Push and hold to enter SHIFT LOCK mode.

Num Key—used to manually enter Num-mode. Click once, then enter a number followed by the space bar. Clicking the Num key once (or twice) momentarily turns-off AutoNum for the current word one is entering. Push and hold the Num key to enter NUM LOCK mode.

The dusty keys application works with QWERTY and all other keyboards and keypad layouts.

Note—in the following examples, a “|” will be used to represent the screen cursor and a “_” will be used to represent a space. shifton( ) means the invention turns shift mode on, shiftoff( ) means the invention turns shift mode off.

Dusty keys studies every keystroke, every word, and every sentence the user types. A word is defined as a contiguous strings of letters, numbers and punctuation bracketed by spaces, punctuation and/or line feeds. For example—“Hello there!” is one sentence with two words, the words being hello and there.

The following is the processing that occurs from the onset:

INITIALIZE Reset variables. Shift mode turned on.

EVERY KEYSTROKE:

IF A LETTER (A-Z), then if a candidate key, process it as a digit, else see if the word or partial word entered so far matches a legal word. If full or partial match (Examples—“tee” partially matches “teeth”, “zulu” fully matches “zulu”), the letters are left alone. If a letter falls out side the list of characters that also represent digits, the defcon is set to “no way” (meaning it can not possibly be a number) and the current word is assumed to be a legal word and no longer a candidate for possible conversion to a number. If the letter is a candidate, if defcon is not set to “no way,” defcon is set to “candidate.” Once in numeric mode (candidate=“numeric”), keystrokes are interpreted and displayed as digits, until a space completes the current word.

IF A SPACE KEY: IF THIS IS THE THIRD OR GREATER CONSECUTIVE SPACES IN A ROW: then append a space to the output stream.

IF THIS IS THE SECOND CONSECUTIVE SPACE IN A ROW, AND ENTER KEY, OR SOFT ENTER, THEN WE HAVE A SENTENCE: sentences are defined and delineated by TWO consecutive Spaces, a Down Arrow, or an Enter key. See if last word should be converted to a number (defcon=“candidate”) and convert if needed. the first word is a “question trigger word” (who, what, why, doesn't, etc.), then a question mark is appended to the sentence, else a period is appended. Set shiftmode on for next sentence.

IF A SINGLE SPACE THEN WE HAVE A WORD: check the word for candidacy and convert if possible else if an apostrophe_word (dont, cant, wouldnt, etc.) insert apostrophe else if an acronym (fbi, fyi, etc.) convert to uppercase else if a cap_first_letter word, (Mr. Ms. etc.) cap first letter. Set defcon to “candidate” for next word.

EVERY ARROW KEY MOVEMENT:

Move to cursor position.

If char_to_left is a CAP AND char_to_right is a space or then shifton else shiftoff.

If char_to_left (aftermove) is a digit, then turn Num Mode on, else turn Num Mode off.

SET SHIFT MODE

shiftoff( )

If (char_to_left OR char_to_right is a CAP) AND char_to_right is NOT a lowercase letter then shifton( ).

Examples: _|H |Z Y|AB|CD turn shift mode on but not: A|b a|bc c|_e|_ _|_etc.

2) SET NUM MODE

numoff( )

If char_to_left OR char_to_right is a digit, then numon( ).

Examples: |7 1,|234 5|,000 8| |123 456| 12.|345 456|_ turn num mode on but not |_{—}9 He|llo etc.

EVERY BACKSPACE: if (before move) chartoleft is a CAP, then shifton else shiftoff. Delete character to left of cursor, move cursor left one position. If char_to_left (aftermove) is a digit, then turn Num Mode on, else turn Num Mode off.

EVERY CHARACTER INSERTED: After character is inserted, the same as EVERY ARROW KEY MOVEMENT (see above).

EVERY DELETE: After character is deleted, the same as an EVERY ARROW KEY MOVEMENT above.

EVERY ENTER: check last word for candacicy and convert if needed. If a question then append a “?” else append a “.”.

Set shift mode on to capitalize the beginning of the next sentence.

EVERY SOFT ARROW KEY like Enter key above but do not append a period or question mark.

PUNC KEY Punctuation has always been a problem on small keypads due to the lack of space for additional punctuation buttons. By using a dedicated Punctuation key, Dusty Keys allows the user to select from over 32 punctuation characters with never more than two keystrokes. By using a dedicated punctuation button to display one or more screens of additional punctuation for the user to pick from, Delta II offers unlimited punctuation. On the Punc screen, each punctuation character is displayed next to a (often) mnemonically related character, to utilize the users “motor memory” to expedite punctuation entry. For example, Q=Quote (”) and is also displayed with Q in upper right corner where user is used to seeing the letter “Q.” The user thinks “Quote,” then thinks “Q,” then instinctively reaches for upper left corner of keypad to press the “Q” key.

HOW AUTONUM WORKS: So as to alleviate a user from having to hit a Num key to enter and exit numeric entery mode, every word and partial word is compared to a list of legal words. If the current word typed so far is not the beginning of a legal word the “word” is converted from letters to numbers.

Example: Referring to the keypad in FIG. 5, the word “tee” can be part of a word such as “teeth”, but “teee” can not be a word, and is therefore converted to the number “2111.” The number “2111” then replaces the word “teee” in memory and on the users display, and the keypad is put into Num mode for possible further entry of digits, for example “2111789.”

Another example: “etu” does not spell a word, but might be the beginning of the word “etude”. Therefore the keypad is left in character mode. If a user then hits a “y,” the invention compares “etuy” to a list of legal words, determines it is NOT a legal word, and converts it to the number “1235”. See FIG. 5.

Every time a word is completed, signified by the user hitting the space bar, the following occurs: A final comparison is made to see if the word is a legal word. If not, the word is converted to a number. Examples: The user has typed “etu” and then a space. The invention looks up “etu” in a list of legal words, determines it is not a legal word, and therefore converts “etu” the number “123”.

Of course, many variations embodying the invention can be envisioned. Various changes in the details and components that have been described may be made by those skilled in the art within the principles and scope of the invention herein described in the specification and defined in the appended claims. Therefore, while the present invention has been shown and described herein in what is believed to be the most practical and preferred embodiments, it is recognized that departures can be made there from within the scope of the invention, which is not to be limited to the details disclosed herein but is to be accorded the full scope of the claims so as to embrace any and all equivalent processes and products.

1. A method of displaying data, comprising the steps of:
invoking a dusty keys software application;
accepting a first datum from a data entry device;
comparing the first datum to a list of legal words;
displaying the first datum as a letter if the first datum corresponds to a legal word;
accepting a second datum from a data entry device;
adding the second datum to the first datum to create a word;
comparing the word to the list of legal words;
displaying the word as a set of letters if the word corresponds to a legal word; and
displaying the word as a number if the word does not correspond to a legal word.

2. An article of manufacture including a data storage medium, said data storage medium including a set of machine-readable instructions that are executable by a processing device to implement an algorithm, said algorithm comprising the steps of:
invoking a dusty keys software application;
accepting a first datum from a data entry device;
comparing the first datum to a list of legal words;
displaying the first datum as a letter if the first datum corresponds to a legal word;
accepting a second datum from a data entry device;
adding the second datum to the first datum to create a word;
comparing the word to the list of legal words;
displaying the word as a set of letters if the word corresponds to a legal word; and
displaying the word as a number if the word does not correspond to a legal word.

3. A digital processing device, comprising:
a data entry device;
a processor;
a display surface; and
a memory device including a list of legal words and a dusty keys software application;
wherein a user enters a first datum into the digital processing device through the data entry device, the first datum is compared by the processor to the list of legal words, and the display surface displays a letter corresponding to the first datum if the first datum corresponds to a legal word.

4. The digital processing device of claim 3, wherein the display surface displays a number corresponding to the first datum if the first datum does not correspond to a legal word.

5. The digital processing device of claim 3, further including:
A dedicated punctuation button, wherein actuation of said punctuation button displays a screen of mappings of punctuation characters and symbols as buttons corresponding to a key on the keyboard or keypad, with letters arranged on the display in the same layout as said letters exist on the keyboard or keypad.

6. A software driver-based method for reducing keystrokes on a keyboard or keypad, wherein if the driver detects two consecutive spaces or detects the “Enter” key hit following any sentence or word, a routine is initiated comprising the following steps:
(a) comparing a first word in the sentence to a list;
(b) placing a question mark at the end of the sentence if the first word is contained in said list;
(c) placing a period at the end of the sentence if the first word is not contained in said list;
(d) setting the “Shift mode” to ON so that a next letter typed after said two consecutive spaces is automatically capitalized, wherein the “Shift mode” is set to OFF following said next letter typed; and
(e) appending and displaying a space after said question mark or said period.

7. The method of claim 5, wherein said list comprises the words: if, were, what's, ready, want, happens, r, y, ru, really, weren't, haven't, wasn't, didn't, hasn't, doesn't, wouldn't, couldn't, shouldn't, shan't, which, how's, what's, where's, who's, why's, when's, weren't, haven't, won't, whom, whose, them, so, aren't, wazup, was, can't, am, have, shall, is, isn't, are, does, who, might, when, where, could, why, how, can, do, should, would, did, and will.
